(19) United States
(12) Patent Application Publication
(10) Pub. No.: US 2011/0175054 A1
(43) Pub. Date: Jul. 21, 2011

(54) DEVICE CONTAINING LARGE-SIZED EMITTING COLLOIDAL NANOCRYSTALS

(76) Inventors: XIAOFAN REN, Rochester, NY (US); KEITH B. KAHEN, Rochester, NY (US)

(21) Appl. No.: 12/688,212

(22) Filed: Jan. 15, 2010

(51) Int. Cl. H01L 33/06; H01L 33/26

(52) U.S. Cl. 257/13; 257/E33.021; 257/E33.027; 257/E33.008; 977/773; 977/774

(57) ABSTRACT

A device using a layer containing emitting semiconductor nanocrystals wherein each emitting nanocrystal includes a core structure wherein the cores have an aspect ratio less than 2:1 and a diameter greater than 10 nanometers and a protective shell surrounding the core

### CROSS-REFERENCE TO RELATED APPLICATIONS

Reference is made to commonly-assigned, co-pending U.S. patent application Ser. No. ______ (Kodak Docket 95788US01) filed concurrently herewith, entitled “PREPARING LARGE-SIZED EMITTING COLLOIDAL NANOCRYSTALS” by Ren et al., the disclosure of which is incorporated herein.

### FIELD OF THE INVENTION

The present invention relates to devices using large-sized emitting nanocrystals, and particularly to large-sized core/shell nanocrystals with ternary ZnCdSe cores.

### BACKGROUND OF THE INVENTION

A quantum dot is a semiconductor whose excitons are confined in all three spatial dimensions. As a result, it has properties that are between those of bulk semiconductors and those of discrete molecules. An immediate optical feature of colloidal quantum dots is their coloration. While the material which makes up a quantum dot defines its intrinsic energy signature, the quantum dots of the same material, but with different sizes, can emit light of different colors. The physical reason is the quantum confinement effect. Quantum confinement results from electrons and holes being squeezed into a dimension that approaches a critical quantum measurement, called the exciton Bohr radius. As with any crystalline semiconductors, a quantum dot's electronic wave functions extend over the crystal lattice. Similar to a molecule, a quantum dot has both a quantized energy spectrum and a quantized density of electronic states near the edge of the band gap.

Colloidal semiconductor quantum dots, or colloidal nanocrystals, have been the focus of a lot of research. They are easier to manufacture in volume than self-assembled quantum dots. Colloidal nanocrystals are synthesized from precursor compounds dissolved in solutions, much like traditional chemical processes. The synthesis is based on a three-component system composed of: precursors, organic surfactants, and solvents. When heating a reaction medium to a sufficiently high temperature, the precursors chemically transform into monomers. Once the monomers reach a high enough supersaturation level, the nanocrystal growth starts with a nucleation process followed by a growth process. Colloidal nanocrystals can be used in biological applications since they are dispersed in a solvent. Additionally, the potential for low cost deposition processes makes colloidal nanocrystals attractive for light emitting devices, such as LEDs, as well as other electronic devices, such as, solar cells, lasers, and quantum computing (cryptography) devices.

With regard to conventional LEDs containing colloidal nanocrystals, colloidal nanocrystals have been incorporated in both inorganic and organic LED devices (FIG. 1 gives a schematic of a typical prior art LED device 105. All of the device layers are deposited on the substrate 100. Above the substrate is the p-contact layer 110, the p-transport layer 120, the intrinsic emitting layer 130, the n-transport layer 140, and the n-contact layer 150. The anode 160 makes ohmic contact with the p-contact layer 110, while the cathode 170 makes ohmic contact with the n-contact layer 150). To improve the performance of OLEDs, in the later 1990's OLED devices containing mixed emitters of organics and quantum dots were introduced (Matoussi et al., J. Appl. Phys. 83, 7965 (1998)). The virtue of adding quantum dots to the emitting layers is that the color gamut of the device could be enhanced; red, green, and blue emission could be obtained by simply varying the quantum dot particle size; and the manufacturing cost could be reduced. Because of problems, such as, aggregation of the quantum dots in the emitter layer, the efficiency of these devices was rather low in comparison with typical OLED devices. The efficiency was even poorer when a neat film of quantum dots was used as the emitting layer (Hikmet et al., J. Appl. Phys. 93, 3509 (2003)). The poor efficiency was attributed to the insulating nature of the quantum dot layer. Later the efficiency was boosted (to ˜1.5 cd/A) upon depositing a monolayer film of quantum dots between organic hole and electron transport layers (Coe et al., Nature 420, 800 (2002)). It was stated that luminescence from the quantum dots occurred mainly as a result of Forster energy transfer from excitons on the organic molecules (electron-hole recombination occurs on the organic molecules). Regardless of any future improvements in efficiency, these hybrid devices still suffer from all of the drawbacks associated with pure OLED devices.

Recently, a mainly all-inorganic LED was constructed (Mueller et al., Nano Letters 5, 1039 (2005)) by sandwiching a monolayer thick core/shell CdSe/ZnS quantum dot layer between vacuum deposited n- and p-GaN layers. The resulting device had a poor external quantum efficiency of 0.001 to 0.01%. Part of that problem could be associated with the organic ligands of trioctylphosphine oxide (TOPO) and trioctylphosphine (TOP) that were reported to be present post growth. These organic ligands are insulators and would result in poor electron and hole injection into the quantum dots. In addition, the remainder of the structure is costly to manufacture, due to the usage of electron and hole semiconducting layers grown by high vacuum techniques, and the usage of sapphire substrates.

For solid-state lighting applications, the fastest route to high efficiency white LEDs is to combine either blue, violet, or near UV LEDs with appropriate phosphors. Replacing traditional optically pumped phosphors with quantum dot phosphors has many advantages, such as, greatly reduced scattering, ease of color tuning, improved color rendering index (CRI), lower cost deposition process, and broader wavelength spectrum for optical pumping. Despite these advantages, quantum dot phosphors have not been introduced into the marketplace due to some major shortcomings; such as, poor temperature stability and insufficient (10-30%) quantum yields for phosphor films with high quantum dot packing densities. In order to raise the quantum yield, many workers have lowered the packing density by incorporating appropriate filler (e.g., polymers or epoxies) with the quantum dots. The disadvantage of this approach is that the resulting quantum dot phosphor films are unacceptably thick (1 mm), as compared to the desired thickness of 10 μm. Therefore, forming colloidal quantum dot phosphors with improved temperature stability and dense-film quantum yield would remove two large hurdles currently preventing the widespread commercial usage of quantum dot phosphors for display and lighting applications.

The most intensively studied semiconductor nanocrystals are II-VI nanocrystals. These nanocrystals have size-tunable luminescence emission spanning the entire visible spectrum. In photoluminescent applications, a single light source can be used for simultaneous excitation of different-sized dots, and their emission wavelength can be continuously tuned by changing the particle size. Since they can also be conjugated to biomolecules, such as, proteins or nucleic acids, this photoluminescence property makes them an attractive alternative for organic fluorescent dyes classically used in biomedical applications. Additionally, the tunable nature of the emission makes quantum dots well suited for full color display applications and lighting. As a result of their well-established high-temperature organometallic synthetic methods (Murray et al, J. Am. Chem. Soc. 115, 8706 (1993)) and their size-tunable photoluminescence (PL) across the visible spectrum, CdSe nanocrystals have become the most extensively investigated quantum dots (QD). A major problem encountered over the years in fabricating high quality colloidal nanocrystals is associated with materials issues, primarily the tendency to form defects and surface trap states under the employed growth conditions, resulting in low luminescence efficiency and insufficient stability. Surface passivation of the CdSe nanocrystals with suitable organic and inorganic materials can minimize this problem by removing the non-radiative recombination centers. Organic passivation is often incomplete and reversible. Effective inorganic-passivation can form core-shell structured QDs (such as CdSe/ZnS and CdSe/CdS) that are more robust than the organic-coated QDs against chemical degradation or photooxidation. However, for the largely mismatched core-shell structures, the interface strain accumulates dramatically with increasing shell thickness, and eventually can be released through the formation of misfit dislocations, degrading the optical properties of the QDs. Furthermore, the luminescence intensity of organically or even inorganically passivated CdSe nanocrystals will dramatically decrease when capping materials (such as alkylamine or trioctylphosphine oxide) are displaced in order to render them water-soluble, or removed to make organic-free nanocrystals. This limits their functionality in biomedical labeling and electronic device applications.

Given the problems associated with CdSe, some researchers are looking at more complex quantum dots with ternary rather than binary compositions. U.S. Pat. No. 7,056,471 by Han et al discloses processes and uses of ternary and quaternary nanocrystals (quantum dots). The nanocrystals described by Han et al are not core/shell quantum dots, rather they are homogeneously alloyed nanocrystals (also referred to as nanoalloys). One material system that was investigated in detail by Han's group is ZnₓCd₁₋ₓ Se (Zhong et al, J. Am. Chem. Soc, 125, 8589 (2003); Zhong et al, J. Phys. Chem. B, 108, 15552 (2004)). In their study, an effective high-temperature synthetic strategy has been developed to make a series of high-quality ZnₓCd₁₋ₓSe alloy nanocrystals with emission wavelengths ranging from 460 to 630 nm by incorporating Zn and Se into pre-prepared starting CdSe nanocrystals. The composition-tunable emission across the visible spectrum has been systematically demonstrated over the composition of the ZnₓCd₁₋ₓSe nanocrystals (the emission wavelength blue-shifts gradually with the increase of Zn content). The resulting alloy nanocrystals have comparable PL properties to CdSe-based QDs. In addition, they can retain their high luminescence when dispersed in aqueous solutions. The high luminescence efficiency and stability of the resulting alloy nanocrystals are attributed to the larger particle size, higher crystallinity, higher covalency, lower inter-diffusion, and spatial composition fluctuation.

Larger sized nanocrystals are more stable than smaller ones as smaller nanocrystals have a higher percentage of reactive surface atoms. Atoms on the surface are energetic less stable than those that are well-ordered and packed in the interior. Larger nanocrystals have much weaker interactions with foreign species, which would lead to less obvious influence on the overall electronic structure of the nanocrystals. However, it has been shown that it is not an easy task to grow colloidal nanocrystals having sizes larger than 5 nm while maintaining the emission intensity. This is because significant amounts of defects are formed as the size becomes larger, which act as the emission quencher. In addition, the overlap between electron and hole wavefunctions in an electron-hole pair becomes smaller on increasing particle size, leading to a reduced radiative rate and, as a result, decreased emission intensity. The largest ZnₓCd₁₋ₓSe nanocrystal reported by Zhong et al. has a diameter about 7.5 nm and emits blue due to the substantial amount of Zn present in the structure. It is believed that this represents the largest II-IV nanocrystal (before shelling) emitting in the visible region that has ever been reported in the open literature.

In order for colloidal nanocrystals to find applications in both biological and electronic device areas, it is important that the nanocrystals have a narrow size distribution and high emission quantum efficiencies. This requirement can be relatively easily met by regular-sized (˜5 nm) nanocrystals. However, many applications also demand nanocrystals that are not only robust but also insensitive to their surface chemistry and surface conditions. Furthermore, the availability of nanocrystals with improved temperature stability is crucial to make possible the widespread commercial usage of quantum dot phosphors for display and lighting applications. It has been demonstrated by our group and others that regular-sized (˜5 nm) nanocrystals are often inadequate meeting all the requirements.

To date, optoelectronic devices or biological (medical) studies have not had emitting colloidal nanocrystals available that have a size larger than 10 nm before the shelling steps. Chen et al has reported II-IV core-shell nanocrystals that has a core size of 3-4 nm and a shell so thick that the final size of the nanocrystals reaches 15-20 nm (Chen et al, J. Am. Chem. Soc, 130, 5026 (2008)). The synthesis took 5 days, and the nanocrystals suffer from wide size distributions and low PL efficiencies. Therefore, there is a need for large-sized colloidal quantum dots with desirable properties for use in biological and optoelectronics applications; and there is a need for a facile method to make such colloidal nanocrystals.

### SUMMARY OF THE INVENTION

In accordance with the present invention, there is provided a device using a layer containing emitting semiconductor nanocrystals, wherein each emitting nanocrystal includes a core structure wherein the cores have aspect ratio less than 2:1 and a diameter greater than 10 nanometers and a protective shell surrounding the core.

### ADVANTAGES

It is an advantage of the present invention to enable a method of making a colloidal solution of large-sized emitting nanocrystals, wherein each emitting nanocrystal includes a core structure wherein the cores have aspect ratio less than 2.1 and a diameter greater than 10 nanometers and a protective shell surrounding the core.

It is also an advantage of the present invention that the colloidal ternary nanocrystals made in accordance with the present method exhibit the desirable properties of high crystallinity, narrow size distribution, high emission efficiency, ability to form polycrystalline films with less than 5% by volume of organic material, high temperature stability, stable fluorescence after removal of organic passivating ligands, and robustness for high temperature anneals.

Another advantage of the present invention is that the large-sized emitting colloidal nanocrystals exhibiting these properties can be used to create advantaged quantum dot phosphors, medical and biological sensors, high efficiency LEDs and lasers.

### BRIEF DESCRIPTION OF THE DRAWINGS

FIG. 1 shows a side-view schematic of a prior art inorganic light emitting device;

FIG. 2 shows a schematic of a colloidal semiconductor nanocrystal;

FIGS. 3A-B shows a representation of Transmission Electron Microscopy (TEM) of the large-sized ZnCdSe nanocrystals;

FIG. 4 shows the PL spectrum of the large-sized ZnCdSe nanocrystals; and

FIG. 5 shows a representation of a photograph of drop-casted films composed of the large-sized ZnCdSe nanocrystals under a UV lamp:

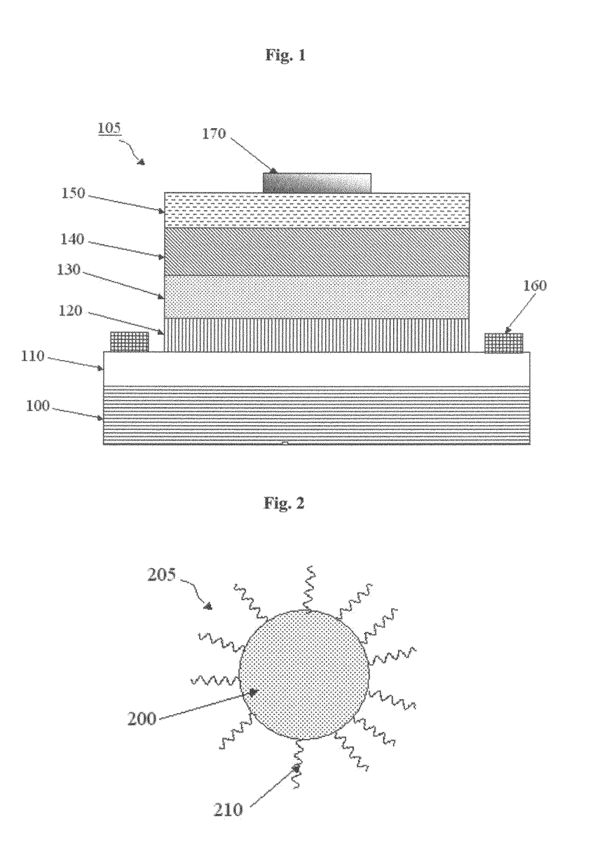

a) Before anneal. Film was made by drop-casting from a EtOH/PrOH solution of the nanocrystals. High boiling point organic ligands are replaced with pyridine (left).

b) After annealed at 160° C. under vacuum for 30 min. At the end of the process, pyridine was removed and the nanocrystals are no longer passivated by organic ligands (middle).

c) After annealed at 270° C. for 15 min following the 160° C. anneal (right).

### DETAILED DESCRIPTION OF THE INVENTION

It is desirable to form devices that not only have good performance, but also are low cost and can be deposited on arbitrary substrates. Using colloidal-based nanocrystals as the building blocks for semiconductor electronic devices would result in devices that confer these advantages as long as the layers can be properly engineered. A typical colloidal inorganic nanocrystal 205 is shown in FIG. 2. In the figure, the inorganic nanocrystal 205 is composed of a semiconductor core 200, on whose surface is bonded organic ligands 210. The organic ligands 210 give stability to the resulting colloidal dispersion (the inorganic nanocrystals 205 and an appropriate solvent). Even though the inorganic nanocrystal 205 shown in FIG. 2 is spherical in shape, nanocrystals can be synthesized to have shapes ranging from quantum rods and wires, to tetrapods and other multiple connected nanocrystals. In addition, a shell is often grown outside the semiconductor core with a semiconducting material having an energy bandgap being higher than that of the core. This bandgap engineering not only moves the exciton-generation zone further away from the surface where quenching can take place, but ensures carrier confinement to the core region.

It is well known in the art that in order to reduce the deleterious effects of surface states on the optical and electrical properties of nanocrystals, it is advantageous to form nanocrystals with the smallest surface to volume ratio, thus, large nanoparticles. Taking the example of II-VI semiconductor nanocrystals, CdSe-based nanocrystals can be used to generate red, green, and blue light, and the quantum size effects dictate the length scale of the nanocrystals. A simple way to increase the size of the nanocrystal while maintaining the emission color is to grow a very thick shell outside of the CdSe core. Formation of the shell is conducted by slowly adding molecular precursors into the core solution at high temperatures in coordination solvents. It is well-known that lattice mismatch between core and shell materials leads to accumulation of interface strain. Such strain eventually would be released through the formation of misfit dislocations that degrade optical properties. Therefore, nanocrystals with thick shells usually have unsatisfactory optical properties.

Another way to increase the size of the nanocrystal while maintaining the emission color is to add some Zn to the CdSe in order to increase the bandgap of the semiconductor material and localize the exciton states. The resulting material is the ternary alloy ZnCdSe. Depending on the synthetic procedure the alloy content is either homogenously distributed throughout the nanocrystal or it can have some radial dependence.

Typically, ternary semiconductor alloys are created by adding, at the start of the synthesis, appropriate ratios of cations (e.g., ZnCdSe) or anions (CdSeTe) into the synthesis reaction mixture (R. Bailey et al., JACS 125, 7100 (2003)). This procedure would normally result in an alloy homogenously distributed throughout the nanocrystal volume. In order to form a radial-dependent composition profile, taking the example of the ZnCdSe system, the synthetic scheme would be to initially create a CdSe core, shell it with ZnSe, and then perform an appropriate anneal (K. Kahen et al. WO 2009058172 A1; K. Kahen et al. WO 2009058173 A1). As is well known in the art, the diffusion profile would be such that the maximum Zn concentration in the nanocrystal would occur at the surface, while in the core center the Zn content would be much lower (ZnCdSe, but with a high Cd/Zn ratio). Given the weakening Zn penetration into the center of the nanocrystal, the surface region of the annealed nanoparticle would show the strongest random alloy attributes, with the core region behaving mainly as crystalline CdSe. As such, e-h pairs created in the core CdSe-like region would not only get localized by the increasing energy gap of the ZnCdSe surface region, but also by carrier localization generated by the band of random alloy surrounding the core region of the nanocrystal.

The size of the ZnCdSe nanocrystals prepared with the methods discussed above is typically 3-5 nm. Larger ZnCdSe nanocrystals, with sizes reaching 7.5 nm, were reported by Zhong et al (J. Am. Chem. Soc, 125, 8589 (2003); J. Phys. Chem. B, 108, 15552 (2004)). The typical solvent/ligand system used to prepare these ZnCdSe nanocrystals includes TOPO, or HDA (or ODA), and about 1-5 wt % fatty acid. The small amount of fatty acid reacts with CdO in situ to form Cd-fatty acid salt that acts as the real Cd precursor for the nanocrystal synthesis. This solvent/ligand system is ideal for synthesizing ZnCdSe nanocrystals with small to medium sizes (less than 8 nm), as has been demonstrated. To make larger-sized ZnCdSe nanocrystals, new solvent/ligand system and synthetic method are needed; and some clues may be drawn in the synthesis of large non-emissive CdSe nanocrystals.

Reports on making binary II-IV nanocrystals having sizes larger than 10 nm are scarce. In the work of Murray et al., CdSe nanocrystals as large as 11.5 nm has been prepared by injecting a mixture of dimethylcadmium and TOPSe into a hot solution of TOPO and TOP [C. B. Murray, et al., JACS, 115, 8706 (1993)]. However, the long hours it takes to reach the size of 11.5 nm, together with the usage of the extremely toxic cadmium precursor CdMe₂, makes this preparation method impractical from a manufacture point of view. In addition, large-sized CdSe nanocrystals synthesized by this method using multiple injections are generally limited to around 11 nm and often with a significant aspect ratio.

Recently, Peng, et al. reported rice-shaped CdSe nanocrystals with a size of up to 30 nm along the long axis and 8-10 nm along the short axis [Z. A. Peng et al., JACS, 124, 3343 (2002)]. These nanocrystals are formed by using a less reactive cadmium precursor, cadmium phosphonic acid complexes, in the presence of large excess of starting materials, and with regular replenish of the monomer concentration. The same experiment was tried out in our lab, and the formation of rice-shaped CdSe nanocrystals was observed, even though the sizes were not as large as reported. The as-formed nanocrystals could be isolated and purified. However, replacing the phosphoric acid bonded on the surface of the nanocrystals with low boiling point pyridine at temperatures near 100° C. failed, most likely due to the strong bonding between cadmium and phosphonic acid. Higher boiling point pyridine analogues, such as 3-methyl pyridine, were also tested so that the ligand exchange reaction could be done at higher temperatures, but to no avail. Due to the presence of long-chain phosphonic acid, the nanocrystal films drop-casted on glass appeared again highly non-uniform, full of pin-holes and large clumps of materials.

More recently, Peng's group investigated different kinds of safe, common, and low-cost organic compounds to be used as coordinating solvents/ligands for the synthesis of high quality II-VI nanocrystals [L. Qu, et al., Nano Letters, 1, 333 (2001)]. Their work shows that among all of the solvent/ligand system tested, fatty acids are excellent candidates for synthesizing relatively large-sized CdSe nanocrystals. Using stearic acid as an example, without secondary injection, a solvent system of 50 wt % of fatty acid and 50 wt % of TOPO yields CdSe nanocrystals in a very broad size range from about 2 nm to 25 nm. Moreover, the shape of the CdSe nanocrystals with a diameter up to 25 nm can be purposely controlled to dot-shape. The ability of fatty acids to enable synthesis of large nanocrystals is believed to come about from the fast growth rates of nanocrystals in this solvent system. This reaction was successfully reproduced and large-sized CdSe nanocrystals were indeed obtained. However, during the process of isolation and purification of these dots, it was found that large amount of white organic impurities was formed during the reaction, which precipitated out of the reaction mixture with the nanocrystals. These white organic impurities have very low solubility in common organic solvents at room temperature. By repeating the process of heating the nanocrystals/white organics mixture in methanol to the boiling temperature and centrifugation while the mixture is still hot for a number of times, the white organics could only partially be removed and a significant amount of nanocrystals were also lost during the process. The remaining white impurities also hindered the following ligand exchange process. As a result, the nanocrystal films drop-casted on glass appeared highly non-uniform, full of pin-holes and large clumps of materials.

Even though the above fatty acid solvent/ligand system could not yield CdSe nanocrystals that can be readily washed and cleaned, adaptation of the method to make large-sized emitting ZnCdSe nanocrystals seems promising, even for the purpose of making organic-free films for use in devices. The Zn precursors would be expected to suppress the formation of the white organics that most likely are the product of high-temperature acid condensation, as they could react with the fatty acid and convert it to its zinc salt.

Accordingly, it is an object of the invention to overcome the limitations of the prior art and to provide emitting semiconductor nanocrystals wherein each emitting nanocrystal includes a core structure that has a diameter greater than 10 nm and a aspect ratio less than 2:1.

This object is solved by a process of producing a colloidal solution of ternary A_{I}A_{II}B nanocrystals having the features of the respective independent claims, wherein
(a) A_{I} and A_{II} are independently selected from an element from the subgroup of IIB of the periodic table, when B represents an element of the main group of VI of the periodic table;
(b) A_{I} and A_{II} are independently selected from an element from the main group of III of the periodic table, when B represents an element of the main group of V of the periodic table;

said process comprising:
(i) providing a mixture of the element A_{I} in a suitable form for the generation of a nanocrystal, and coordinating solvents including at least 30 wt % of fatty acids.
(ii) heating the reaction mixture to a suitable temperature T1 for a suitable time, then adding to the solution the element B in a suitable form for the generation of a nanocrystal, and then adding A_{II} in a suitable form for the generation of a nanocrystal.
(iii) heating the reaction mixture for a sufficient period of time at a temperature T2 suitable for forming said nanocrystal A_{I}A_{II}B.

Finally, an outer shell is grown on the ternary core with a semiconducting material having an energy bandgap being higher than that of the ternary core. Since shelling with III-V compounds remains problematic, it is preferred that the shell material also is composed of II-VI semiconducting material, with either a binary or a ternary alloy composition. Examples are ZnS, ZnSe, ZnSeS, ZnSeTe, or ZnSeS. It is well-known that large lattice mismatch between core and shell materials leads to accumulation of interface strain. Such strain eventually can be released through the formation of misfit dislocations that degrade optical properties. Therefore, it is advantageous that the shell material is chosen such that the difference between the crystal lattice values of the shell and ternary core materials is small.

The preferred temperature range for T1 and T2 is between 250° C. to 400° C., and more preferably between 290° C. to 360° C. It is preferable that T2 is equal to or lower than T1. It should be noted that if a solvent with lower boiling point is used, the inventive process disclosed here can also be carried out at lower temperatures, as long as the desired nanocrystals are obtained.

In the present invention, the column II element comprised herein is preferably independently selected from the group consisting of Zn, Cd and Hg. The column VI element comprised herein is preferably independently selected from the group consisting of S, Se and Te. Preferred embodiments are nanocrystals having the composition ZnₓCd₁₋ₓSe, ZnₓCd₁₋ₓS, ZnₓCd₁₋ₓTe, or HgₓCd₁₋ₓSe.

In the present invention, the column III element comprised herein is preferably independently selected from the group consisting of Al, Ga and In. The column V element comprised herein is preferably independently selected from the group consisting of P, As and Sb. Preferred embodiments are nanocrystals having the composition AlₓIn₁₋ₓP, GaₓIn₁₋ₓP, AlₓIn₁₋ₓAs, or GaₓIn₁₋ₓAs.

In the ternary nanocrystals of the present invention, the index x has a value of 0.001<x<0.999, preferably of 0.01<x<0.99, or more preferred of 0.05<x<0.95 or 0.1<x<0.9. In even more preferred embodiments, x can have a value between about 0.2 or about 0.3 to about 0.8 or about 0.9.

Although it is preferable that the cation precursor used for synthesizing the ternary core is a group II or group III material selected from a group of Cd, Zn, Hg, Al Ga, In, and more preferable that the group II or group III cation precursor is a chemical compound selected from a group including Cd(Me)₂, CdO, CdCO₃, Cd(Ac)₂, CdCl₂, Cd(NO₃)₂, CdSO₄, ZnO, ZnCO₃, Zn(Ac)₂, Zn(Et)₂, Hg₂O, HgCO₃, Hg(Ac)₂, In(Ac)₂, Ga(Me)₃, Ga(acac)₃, InCl₃ or Al(Me)₃. Any compound including the group II and the group III metals such as Cd, Zn, Hg, In, Ga, and Al can be used without a limitation.

It is preferable that the anion precursor used in the synthesis is a material selected from a group consisting of sulfide(S), selenium (Se), tellurium (Te), phosphorus (P), arsenic (As), and antimony (Sb). It is further preferable that the anion precursor is selected from a group including bis(trimethylsilyl)sulfide, tri-n-alkylphosphine sulfide, hydrogen sulfide, tri-n-alkenylphosphine sulfide, alkylamino sulfide, alkenylamino sulfide, tri-n-alkylphosphine selenide, alkenylaminoe selenide, tri-n-alkylamino selenide, tri-n-alkenylphosphine selenide, tri-n-alkylphosphine telluride, alkenylaminoe telluride, tri-n-alkylamino telluride, tri-n-alkenylphosphine telluride, Tris(trimethylsilyl)phosphine, or bis(trimethylsilyl)arsenide. The element form of the anion can also be used, such as S, Se, Te, P and As. Other appropriate anion precursors can also be used without a limitation.

A wealth of suitable high boiling point compounds exist that can be used both as reaction media and, more importantly, as coordination ligands to stabilize the cation or anion. They also aid in controlling particle growth and impart colloidal properties to the nanocrystals. Among different types of the coordination ligands that can be used are alkyl phosphine; alkyl phosphine oxide, alkyl phosphite; alkyl phosphate; alkyl amine; alkyl phosphonic acid; or fatty acid. The alkyl chain of the coordination ligand is preferably a hydrocarbon chain of length greater than 4 carbon atoms and less than 30 carbon atoms, which can be saturated, unsaturated, oligomeric in nature. It can also have aromatic groups in its structure.

Specific examples of the suitable coordination ligands and ligand mixture include but are not limited to trioctylphosphine, tributylphosphine, tri(dodecyl)phosphine, trioctylphosphine oxide, tributylphosphite, trioctyldecyl phosphate, trilauryl phosphate, tris(tridecyl)phosphate, triisodecyl phosphate, bis(2-ethylhexyl)phosphate, tris(tridecyl)phosphate, hexadecylamine, oleylamone, octadecylamine, bis(2-ethylhexyl)amine, octylaime, dioctylaime, cyclododecylamine, n,n-dimethyltetradecylamine, n, n-dimethyldodecylamine, phenylphosphonic acid, hexyl phosphonic acid, tetradecyl phosphonic acid, octylphosphonic acid, octadecyl phosphonic acid, propylphosphonic acid, aminohexyl phosphonic acid, oleic acid, stearic acid, myristic acid, palmitic acid, lauric acid, and decanoic acid.

Further, it can be used by diluting the coordination ligands using at least one non-coordinating or weakly coordinating solvent selected from a group including but not limited to 1-nonadcene, 1-octadecene, cis-2-methyl-7-octadecene, 1-heptadecene, 1-pentadecene, 1-tetradecenedioctylether, dodecyl ether, hexadecyl ether, esters and the like. Furthermore, the non-coordinating or weakly coordinating solvent, such as 1-octadecene, esters, ethers, or the combinations thereof, can be used alone without the more strongly coordinating ligands.

It should be noted here that the use of large amount of fatty acids is crucial in the formation of large-sized emitting ternary nanocrystals. The weight percentage of fatty acids in the total ligand/solvent mixture is preferably no less than 30%, and more preferably no less than 40%.

Having grown the emitting nanocrystals 205, it is then necessary to create a layer composed of them in order to apply these nanocrystals in devices. As is well known in the art, three low cost techniques for forming nanocrystal films are depositing the colloidal dispersion of the nanocrystals by drop casting, spin coating and inkjetting. Common solvents for drop casting or spin coating colloidal nanocrystals are a 9:1 mixture of hexane:octane [C. B. Murray et al., Annu. Rev. Mater. Sci. 30, 545 (2000)]. The organic ligands 210 need to be chosen such that the colloidal nanocrystals 205 are soluble in non-polar solvents. As such, organic ligands with hydrocarbon-based tails are good choices, such as, the alkylamines. Using well-known procedures in the art, the ligands coming from the growth procedure (trioctylphosphine oxide, for example) can be exchanged for the organic ligand 210 of choice [C. B. Murray et al., Annu. Rev. Mater. Sci. 30, 545 (2000)]. When spin coating a colloidal dispersion of nanocrystals 205, the requirements of the solvents are that they easily spread on the deposition surface and the solvents evaporate at a moderate rate during the spinning process. It was found that alcohol-based polar solvents are a good choice; for example, combining a low boiling point alcohol, such as, ethanol, with higher boiling point alcohols, such as, a butanol-hexanol mixture or 1-propanol, results in good film formation. Correspondingly, ligand exchange can be used to attach an organic ligand 210 (to the nanoparticles 205) whose tail is soluble in polar solvents; pyridine is an example of a suitable ligand. After formation of the nanocrystal films, it is preferred that the organic ligands 210 attached to the colloidal nanocrystals 205 evaporate as a result of annealing the films in an inert atmosphere or under vacuum. By choosing the organic ligands 210 to have a low boiling point (less than 200° C.), they can be made to evaporate from the film during an annealing process [C. B. Murray et al., Annu. Rev. Mater. Sci. 30, 545 (2000)] where the anneal temperature is below 220° C., or in multiple steps where sequentially each step has a greater temperature than the prior step. Consequently, for films formed by drop casting or spin coating with non-polar solvents, shorter chained primary amines, such as, hexylamine are preferred; for films formed with polar solvents, pyridine is a preferred ligand.

For enabling the dispersion of the nanocrystals in various solvents, appropriate surface functionalization organic ligands can be represented by Xx(Y)nZz, wherein X is, for example, SH, NH₂, P, P═O, CSSH, or aromatic heterocycles; Z is, for example, OH, NH₂, NH₃⁺, COOH, or PO₃²⁻; and (Y)n is, for example, a material mainly having a structure of a saturated or unsaturated hydrocarbon chain, or an aryl that connects X and Y. It is preferable that a particularly suitable material is any material selected from a group including pyridine, pyridine derivatives, mercapto-alkyl acid, mercapto-alkenyl acid, mercapto-alkyl amine, mercapto-alkenyl amine, mercapto-alkyl alcohol, mercapto-alkenyl alcohol, dihydrolipolic acid, alkylamino acid, alkenyl amino acid, aminoalkylcarboic acid, hydroxyalkylcarboic acid or hydroxyalkenylcarboic acid, but it is not limited to these materials as is well known in the art.

The solvents used for making the dispersion of the nanocrystals functionalized with low-boiling-point coordinating ligands include, but are not limited to, toluene, hexane, heptane, octane, ethanol, methanol, propanol, pyridine, pyridine derivatives, or combinations thereof.

After removing the low boiling point organic ligands by annealing, the resulting film comprises the large-sized semiconductor nanocrystals having an aspect ratio less than 2:1 and diameter greater than 10 nm, wherein the film has less than 10%, and more preferably less than 5%, by volume of organic materials. The diameter of the semiconductor nanocrystals comprising the film can also be greater than 12 nm, or even 14 nm. In one embodiment, the nanocrystals comprising the film and device have less than 5% by surface area functionalized with organic ligands. In another embodiment of the film, the nanocrystals comprising the film and device are substantially spherical in shape.

Colloidal semiconductor nanocrystals have been the subject of intensive experimental and theoretic study because of their emission phenomena associated with quantum confinement. The large-sized semiconductor nanocrystals disclosed in the present invention emit strongly in the visible region, with a light emission efficiency no less than 30%, and in most cases, no less than 40%. Despite the large size, the size distribution of the as-prepared nanocrystals is very narrow, with a FWHM in the range of 20-35 nm, and in most cases, 20-25 nm. These highly luminescent, stable nanocrystals are potential ideal nano-emitters for light-emitting devices, quantum information devices, solar cells, or semiconductor lasers in optoelectronic applications. They are also very promising biological labels.

An application for incorporating emitting nanocrystals in light emitting devices is to employ them as emissive phosphors that are optically pumped by a higher energy (the wavelength of the pump source is shorter than the average emission wavelength) light source. The light source can be an LED (either organic or inorganic), a laser, a compact fluorescent lamp, or any other incoherent light source that is well known in the art. The phosphors can be used to produce white light, convert higher energy light into a specific visible wavelength band (for example, produce green light), or any other desired wavelength conversion (including producing infrared light) as is well known in the art. As discussed above, there are many advantages to replacing conventional phosphors by quantum dot phosphors; however, their usage in product is hampered by their poor temperature performance and low quantum efficiency in dense phosphor films. The thermal stability of the large-sized emitting nanocrystals is much higher than traditional nanocrystals, such as CdSe. When examined in toluene solution up to 100° C., the emission intensity loss was only about 20%, compared to that at room temperature. Further increase of temperature to 150° C. (in octadecene) led to intensity drop to 72% of what's originally observed at room temperature. At the same time, the emission color only shifted a few nanometers to the red over the entire temperature range (see Example section). This observation demonstrated the excellent thermal stability of these large-sized nanocrystals, and their potential as emissive phosphors. Moreover, the dense films of the large-sized nanocrystals showed intense emission under the UV light, implying insignificant self-absorption, which is very likely associated with the large stoke shift observed from these nanocrystals.

The excellent thermal and environmental stability, and the robustness of these large-sized emitting nanocrystals can also be demonstrated by the thin film studies. The as-prepared colloidal nanocrystals was ligand-exchanged with the low-boiling point pyridine and drop-casted from a EtOH/PrOH solution on a glass substrate to form a smooth and pinhole-free film. The film showed intense emission under the UV light. The film was then sealed in a glass tube under the inert atmosphere and subjected to a 160° C. anneal under vacuum for 30-45 min. At the end of the process, all the pyridine ligand was expected to evaporate off, and the nanocrystals were no longer passivated by organic ligands. Typical II-IV nanocrystals going through such treatment would lose majority of the emission, or become completely non-emissive. In contrast, no detectable emission intensity loss was observed for the film made with the large-sized nanocrystals prepared with the method disclosed in this invention. To further test the thermal and environmental stability of the nanocrystals, the same film was put back to the tube-oven and annealed at 270° C. for 15-25 min under nitrogen. After cooling down, the film still emitted fairly bight (see Example section). This experiment demonstrated the exceptional thermal and environmental stability, and robustness of these large-sized emitting nanocrystals.

It is an object of this invention to provide large-sized emitting nanocrystals for use in medical, biological, solar cell, lighting and display applications. This object is achieved by a device using a layer containing emitting semiconductor nanocrystals, wherein each emitting nanocrystal includes a core structure wherein the core has a aspect ratio less than 2:1 and a diameter greater than 10 nanometers and a protective shell surrounding the core. The device can be an optoelectronic device, and the optoelectronic device can be a display backlight, multicolor display, full color display, monochrome display or lighting device.

The nanocrystal layer in the device can be formed by co-depositing small (<2 nm), conductive inorganic nanoparticles along with the large-sized emitting nanocrystals 205 to form the inorganic light emitting layer. A subsequent inert gas (Ar or N₂) anneal step can be used to sinter the smaller inorganic nanoparticles amongst themselves and onto the surface of the large-sized emitting nanocrystals 205. Sintering the inorganic nanocrystals results in the creation of a continuous, conductive semiconductor matrix. Through the sintering process, this matrix is also connected to the large-sized emitting nanocrystals 205 and forms a polycrystalline inorganic light emitting layer. As such, a conductive path is created from the edges of the inorganic light emitting layer, through the semiconductor matrix and to each large-sized emitting nanocrystals 205, where electrons and holes recombine in the large-sized emitting nanocrystals 205. It should also be noted that encasing the large-sized emitting nanocrystals 205 in the conductive semiconductor matrix has the added benefit that it protects the nanocrystals environmentally from the effects of both oxygen and moisture.

This object is further achieved by an inorganic light emitting device including a plurality of independently controlled light emitting elements, wherein at least one light emitting element comprises: a first patterned electrode; a second electrode opposed to the first electrode; and a polycrystalline inorganic light emitting layer comprising emitting semiconductor nanocrystals (the emitting semiconductor nanocrystals could be embedded within a semiconductor matrix formed between the electrodes), wherein the emitting semiconductor nanocrystal has a core structure wherein the core has a aspect ratio less than 2:1 and a diameter greater than 10 nanometers and a protective shell surrounding the core. Such an inorganic light emitting device can be used as a display backlight, multicolor display, full color display, monochrome display or lighting device.

The emissive semiconductor material used in a device is type II-VI or III-V semiconductor material having a ternary composition. In the present invention, the column II element comprised herein is preferably independently selected from the group consisting of Zn, Cd and Hg. The column VI element comprised herein is preferably independently selected from the group consisting of S, Se and Te. Thus, all ternary combinations of these elements are within the scope of the invention. Preferred embodiments are nanocrystals having the composition ZnₓCd₁₋ₓSe, ZnₓCd₁₋ₓS, ZnₓCd₁₋ₓTe, HgₓCd₁₋ₓSe, ZnSeₓS₁₋ₓ, ZnSeₓTe₁₋ₓ, CdSeₓS₁₋ₓ, or CdSeₓTe₁₋ₓ.

In the present invention, the column III element comprised herein is preferably independently selected from the group consisting of Al, Ga and In. The column V element comprised herein is preferably independently selected from the group consisting of P, As and Sb. Thus, all ternary combinations of these elements are within the scope of the invention. Preferred embodiments are nanocrystals having the composition AlₓIn₁₋ₓP, GaₓIn₁₋ₓP, Alₓin₁₋ₓAs, GaₓIn₁₋ₓAs, or InPₓAs₁₋ₓ.

In one embodiment, the semiconductor material is type III-V semiconductor material selected from but not limited to AlₓIn₁₋ₓP, AlₓIn₁₋ₓAs, or GaₓIn₁₋ₓAs. In another embodiment, the semiconductor material is type II-VI semiconductor material selected from but not limited to ZnₓCd₁₋ₓse, ZnₓCd₁₋ₓS, ZnₓCd₁₋ₓTe, HgₓCd₁₋ₓSe, ZnSeₓS₁₋ₓ, or ZnSeₓTe₁₋ₓ.

In the ternary nanocrystals of the present invention, the index x has a value of 0.001<x<0.999, preferably of 0.01<x<0.99, or more preferred of 0.05<x<0.95 or 0.1<x<0.9. In even more preferred embodiments, x can have a value between about 0.2 or about 0.3 to about 0.8 or about 0.9.

It is within the scope of the present invention that the emitting semiconductor material used in a device has less than 5% by area of the surface functionalized with organic ligands. Removal of the majority of the insulting organic ligands facilitates both charge transporting through the polycrystalline inorganic light emitting layer comprising the large-sized emitting semiconductor nanocrystals, and direct charge recombination in the emitting nanocrystals. The diameter of the semiconductor nanocrystals can also be greater than 12 nm, or even 14 nm, with an aspect ratio less than 2:1. In one embodiment of the device, the large-sized emitting nanocrystals are substantially spherical in shape. In another embodiment of the device, the large-sized semiconductor nanocrystals emit strongly in the visible region, with a light emission efficiency no less than 30%, and more preferably, no less than 40%.

It is also within the scope of the present invention that the polycrystalline inorganic light emitting layer comprising emitting large-sized semiconductor nanocrystals is formed by a mixture of large-sized nanocrystals having different compositions, or a mixture of large-sized and small-sized emitting nanocrystals having the same, or different compositions.

### EXAMPLE 1

The cadmium precursor is cadmium acetate, the zinc precursor is Zn(Et)₂, and the selenium precursor is TOPSe. The coordinating solvent for the growth is a mixture of trioctylphosphine oxide (TOPO), trioctylphosphine (TOP) and stearic acid. TOPO and TOP are degassed at 190° C. for 60 minutes prior to their usage. Inside a dry box, 0.046 g (0.2 mmol) cadmium acetate and 3 g stearic acid were added into a three-neck flask. The flask was placed on a Schlenk line and vacuum was applied. The mixture went clear after heating at 100° C. for 5-10 minutes. After cooling down, the flask was transferred into the box, and 1.1 ml TOPO was added. The mixture was degassed at 100° C. for 30 minutes. After switching to argon overpressure, the flask contents were taken up to 350° C., and 1 ml TOPSe solution in TOP prepared by dissolving 0.7896 g (10 mmol) Se in 10 ml Top in the dry box was added into the solvent mixture by quick injection from a syringe, followed by the injection of a ZnEt₂ solution in TOP (Zn:Cd ratio varies from 2:1 to 8:1). After the injection, the reaction mixture was stirred at 300° C. for 1 hour. The reaction was stopped by removing the heating source.

The final step in the process was shelling of the ZnCdSe ternary cores. A three-neck reaction flask loaded with 500 μl as-prepared crude ZnCdSe cores, 3 ml TOPO and 2 ml HDA was heated to 190° C. The solution of ZnEt₂ (1 M, 0.8 ml) and TOPSe (1M, 1.2 ml) in 2 ml TOP was slowly added dropwise under vigorous stirring. After the addition the temperature was lowered to 180° C. and the solution was left to stir for another hour to form ZnₓCd₁₋ₓSe/ZnSe nanocrystals.

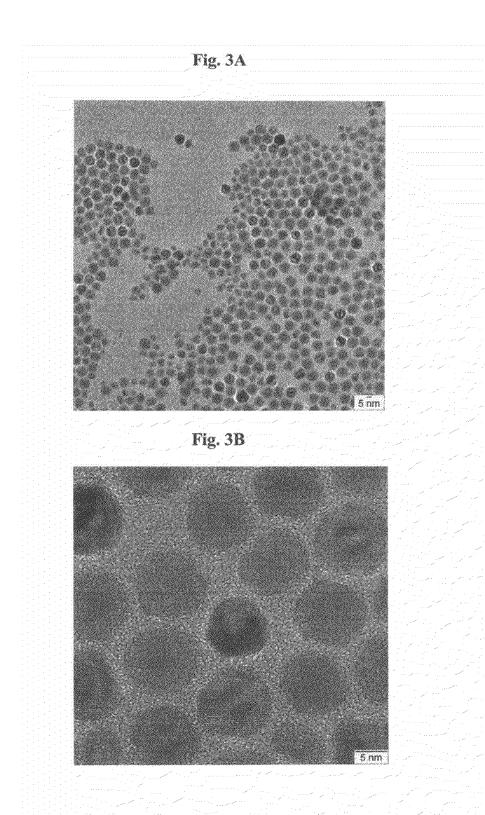

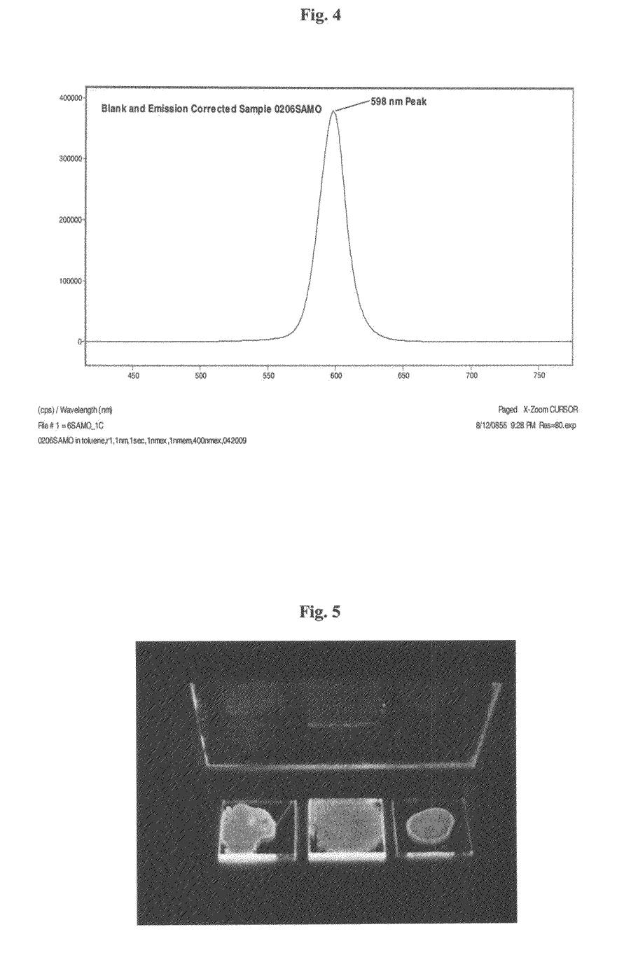

Without any size selective precipitation, TEM analysis revealed the formation of ZnₓCd₁₋ₓSe/ZnSe nanocrystals in a size range from 10 nm to 15 nm (FIG. 3A-B). Photoluminescence measurement showed that the large-sized emitting nanocrystals have emission quantum yield up to 50% and FWHM as narrow as 21 nm (FIG. 4).

After having formed the large-sized emitting nanocrystals 205, dispersions were created with alcohols as the solvents. More specifically, ˜1 ml of the crude solution was added to 3 ml of toluene, and 10 ml of methanol in a centrifuge tube. After centrifuging for a few minutes, the supernatant became clear. It was decanted off and 3-4 ml of pyridine was added. The plug quickly dissolved in the pyridine to produce a clear solution. The solution was heated at 80° C. under continuous stirring for 24 hours in order to exchange the TOPO/stearic acid/TOP organic ligands 210 for pyridine organic ligands 210. Some of the excess pyridine was then removed by a vacuum prior to adding ˜12 ml of hexane to the pyridine solution. This solution was then centrifuged, the supernatant decanted, and a mixture of 1-propanol and ethanol was added to the plug in order to get a clear dispersion. Continuous and smooth nanocrystal-based films were obtained upon drop coating the dispersions on clean borosilicate glass. The films were then annealed in a tube furnace (under vacuum or with flowing argon) at 160° C. for 30 minutes to evaporate pyridine ligand 210. No detectable emission intensity loss was observed after the 160° C. anneal. The same film was then put back to the tube furnace and annealed at 270° C. for 15-25 min under nitrogen. After cooling down, the film still emitted fairly brightly (FIG. 5).

The temperature stability tests were carried out over the temperature range 25° C. to 150° C. For temperatures up to 100° C., the sample was prepared with 800 μl as prepared ZnₓCd₁₋ₓSe/ZnSe nanocrystals dissolved in 3 ml toluene. Over 100° C., 1-octadecene (ODE) was used as the solvent instead of toluene, due to the low boiling point of the latter. Luminance data were recorded relative to the luminance of the toluene sample at room temperature (Table 1). Due to the slight discrepancy between the luminance of the toluene and ODE samples observed at the same temperatures, data for the ODE sample were adjusted so that the luminance at 100° C. for both toluene and ODE solutions are consistent.

TABLE 1
Temperature stability of the large-sized emitting nanocrystals

| T (° C.) | Luminance | CIE(x, y) |
|---|---|---|
| 25 | 1 | 0.599, 0.396 |
| 50 | 0.84 | 0.608, 0.386 |
| 80 | 0.91 | 0.618, 0.377 |
| 100 | 0.81 | 0.625, 0.370 |
| 125 | 0.80 | 0.632, 0.372 |
| 150 | 0.72 | 0.630, 0.366 |

The invention has been described in detail with particular reference to certain preferred embodiments thereof, but it will be understood that variations and modifications can be effected within the spirit and scope of the invention.

### PARTS LIST

100 substrate
105 light emitting diode device
110 p-contact layer
120 p-transport layer
130 intrinsic emitter layer
140 n-transport layer
150 n-contact layer
160 anode
170 cathode
200 semiconductor core
205 inorganic nanoparticle
210 organic ligand

1. A device using a layer containing emitting semiconductor nanocrystals wherein each emitting nanocrystal includes a core structure wherein the cores have an aspect ratio less than 2:1 and a diameter greater than 10 nanometers and a protective shell surrounding the core.

2. The device of claim 1 wherein the device is an optoelectronic device comprising at least one layer containing emitting nanocrystals wherein each emitting nanocrystal includes a core structure wherein the cores have aspect ratio less than 2:1 and a diameter greater than 10 nanometers and a protective shell surrounding the core.

3. The optoelectronic device of claim 2 wherein the device is a display backlight or a solid-state light source.

4. An inorganic light emitting device including a plurality of independently controlled light emitting elements, wherein at least one light emitting element comprises: a first patterned electrode; a second electrode opposed to the first electrode; and a polycrystalline inorganic light emitting layer comprising emitting semiconductor nanocrystals wherein each emitting nanocrystal includes a core structure wherein the cores have aspect ratio less than 2:1 and a diameter greater than 10 nanometers and a protective shell surrounding the core.

5. The inorganic light emitting device of claim 4 wherein the device is a display backlight, multicolor display, full color display, monochrome display or lighting device.

6. The device of claim 1 wherein the emitting semiconductor nanocrystals are formed from type II-VI, III-V semiconductor materials.

7. The device of claim 1 wherein the emitting semiconductor nanocrystals have less than 5% by area of the surface functionalized with organic ligands.

8. The device of claim 6 wherein the II-VI or III-V semiconductor materials are ternary.

9. The device of claim 8 wherein emitting semiconductor nanocrystal is ZnₓCd₁₋ₓSe, ZnₓCd₁₋ₓS, ZnₓCd₁₋ₓTe, ZnSeₓS₁₋ₓ, ZnSeₓTe₁₋ₓ, CdSeₓS₁₋ₓ, CdSeₓTe₁₋ₓ, InₓAl₁₋ₓP, InₓGa₁₋ₓP, or InPₓAs₁₋ₓ.

10. The device of claim 1 wherein each emitting nanocrystal includes a core structure wherein the cores have a aspect ratio less than 2:1 and a diameter greater than 12 nanometers.

11. The device of claim 10 wherein each emitting nanocrystal includes a core structure wherein the cores have a aspect ratio less than 2:1 and a diameter greater than 14 nanometers.

12. The device of claim 1 wherein the emitting semiconductor nanocrystals are substantially spherical in shape.

13. The device of claim 4 wherein the polycrystalline inorganic light emitting layer is a film of a colloidal dispersion of the emitting large-sized nanocrystals and semiconductor matrix nanoparticles.

14. The device of claim 1 wherein the light emission efficiency of the emitting semiconductor nanocrystals is no less than 30 percent.
